(19) United States
(12) Patent Application Publication
(10) Pub. No.: US 2013/0061805 A1
(43) Pub. Date: Mar. 14, 2013

(54) EPITAXIAL WAFER SUSCEPTOR AND SUPPORTIVE AND ROTATIONAL CONNECTION APPARATUS MATCHING THE SUSCEPTOR

(71) Applicant: JiangSu Zhangsheng Semiconductor Equiment Co, Jiangsu (CN)

(72) Inventors: Xiaoliang Jin, Shanghai (CN); Aihua Chen, Shanghai (CN); Renjun Sun, Shanghai (CN); Wei Zhang, Shanghai (CN)

(73) Assignee: JiangSu Zhongsheng Semiconductor Equipment Co., Ltd., Jiangsu (CN)

(21) Appl. No.: 13/670,933

(22) Filed: Nov. 7, 2012

Related U.S. Application Data
(63) Continuation of application No. PCT/CN2011/001147, filed on Jul. 12, 2011.

(30) Foreign Application Priority Data
Aug. 19, 2010 (CN) 201010263418.3

(51) Int. Cl. C23C 16/458

(52) U.S. Cl. 118/725; 118/730

(57) ABSTRACT

Disclosed is an epitaxial wafer susceptor and a supportive and rotational connection apparatus matching the susceptor used for an MOCVD reaction chamber. The susceptor comprises a top surface and a susceptor rotating shaft protruding downward. A vertical driving shaft is coupled to the susceptor. The driving shaft comprises a counter bore inside an upper end of the driving shaft. At least a part of the susceptor rotating shaft is inserted into the counter bore if the susceptor is loaded. The susceptor is positioned and supported in the reaction chamber via coupling and connection between a contact surface of the susceptor rotating shaft and a corresponding contact surface of the counter bore. The susceptor is driven to rotate by the driving shaft if the driving shaft rotates. Reactant gases are introduced into the reaction chamber for an epitaxial reaction or a film deposition on the epitaxial wafers placed on the susceptor.

The present application is a continuation of PCT application PCT/CN2011/001147, filed on Jul. 12, 2011, titled “EPITAXIAL WAFER SUSCEPTOR AND SUPPORTIVE AND ROTATIONAL CONNECTION APPARATUS MATCHING THE SUSCEPTOR”, which claims the priority of Chinese Application No. 201010263418.3 filed on Aug. 19, 2010, titled “EPITAXIAL WAFER SUSCEPTOR AND SUPPORTIVE AND ROTATIONAL CONNECTION APPARATUS MATCHING THE SUSCEPTOR”, which is incorporated herein by reference in its entirety.

### FIELD OF THE INVENTION

The present invention relates to an epitaxial wafer susceptor placed and removed via a robotic arm in a metal organic chemical vapour deposition (MOCVD) system for producing compound semiconductor photoelectric devices, and a connection apparatus matching the susceptor for supporting the susceptor at the center and driving the susceptor to rotate.

### BACKGROUND OF THE INVENTION

Metal organic chemical vapour deposition system (hereinafter referred to as MOCVD system) is an equipment for epitaxially growing a semiconductor film to form a semiconductor device such as light emitting diode (LED).

During mass production, the system output is usually improved via batch processing mode, wherein a batch of epitaxial wafers 40 (or referred to as substrates or substrate sheets) are placed together into a reaction chamber of an MOCVD system, and after the epitaxial growth is completed, the epitaxial wafers are replaced with a new batch of epitaxial wafers 40 for the next reaction processing. A plurality of epitaxial wafers 40 are placed on the same substrate susceptor 10 (FIG. 1). Automatic production requires that the susceptor 10 is loaded and unloaded in the reaction chamber via a robotic arm for realizing the batch processing of simultaneous epitaxial growth and simultaneous placement and removal of the above batch of epitaxial wafers 40.

A heater is generally provided under the epitaxial wafer susceptor for heating the susceptor via heating elements arranged around the center of the susceptor. Because of the design limitations and manufacture differences, the temperature of each point of the heater cannot be exactly the same, and the temperature of the susceptor in radial direction can be uniformed and evened by rotating the susceptor during heating. Additionally, the rotation of the susceptor is also a key control measure for obtaining boundary conditions, such as uniform gas concentration and uniform gas speed, on the surfaces of a plurality of epitaxial wafers. Therefore, it is required that the rotating speed of the susceptor should be adjustable in a large range and the susceptor should be operable steadily in the required rotating speed range.

At present, there exist two typical modes for supporting the susceptor and driving the susceptor to rotate. As shown in FIG. 2, an MOCVD system for supporting the susceptor and driving the susceptor to rotate through the edge is illustrated. In the reaction chamber of the MOCVD system, a supporting cylinder 51 is provided, which supports the susceptor 10 by contacting the edge location of the susceptor 10 on which several epitaxial wafers 40 are placed from below, ensuring that the center of the susceptor 10 is within the supporting surface, and thus the susceptor 10 is very stable in static state. The heating elements of a heater 30 may be provided under the susceptor, especially provided continuously under the center location of the susceptor, so as to ensure that the temperature environment at the center of the susceptor 10 is consistent with the temperature environment at other locations.

However, the rotation of the susceptor 10 is driven via a driving shaft 20 at the middle location under a base 511 of the supporting cylinder 51, wherein a large number of components are used for transmitting rotation. Therefore, it is difficult to regulate the levelness and dynamic balance of the susceptor 10. Moreover, the rotational inertia is large because of the large number of components. Therefore, this type of apparatus that supports the susceptor 10 and drives the susceptor 10 to rotate through the edge is generally applicable to the case of low-speed rotation.

As shown in FIG. 3 or FIG. 4, it shows an MOCVD system where the susceptor 10 is supported and driven to rotate through the center. Wherein, a concave counter bore 101 is set at the middle location of the bottom of the susceptor 10, and the bottom surface thereof is parallel to the top surface of the susceptor 10. Correspondingly, the cylindrical or conic part 201 on top of the driving shaft 20 is vertically inserted into the counter bore 101 of the susceptor 10, for matching the counter bore 101 in the form of a cylinder (FIG. 3) or a cone (FIG. 4). The supporting surface of the susceptor 10 is formed by contacting the surface of the driving shaft 20 with the surface of the counter bore 101 of the susceptor 10, and the susceptor 10 is driven to rotate via the driving shaft 20 by friction.

Because the structure is simple and the components are fewer, the dynamic balance of this type of MOCVD system is easy to regulate, and it is also easy to place and remove the susceptor 10 via a robotic arm. Moreover, because fewer components are used, the rotational inertia is relatively small, and it is able to be applied to the case of high-speed and medium-speed rotation; and the rotation speed of the susceptor 10 may follow the rotating speed of the driving shaft 20 via friction transmission, thus it is convenient for speed control.

When graphite is employed as the material of the susceptor 10, in order to enhance the friction and antifriction performance of the contact surface, a special surface treatment is required. However, because the contact surface is within the counter bore 101, the difficulty of surface treatment is increased.

When a counter bore 101 is machined on the susceptor 10, the thickness of the corresponding part of the susceptor 10 is reduced, and thus the mechanical strength is reduced. In order to guarantee the mechanical strength at the corresponding part of the counter bore 101, generally the overall thickness of the susceptor 10 is increased, and thus the weight of the susceptor 10 is increased and the thermal capacity is increased, and the time required for heating or cooling is prolonged.

### SUMMARY OF THE INVENTION

It is an object of the present invention to provide an epitaxial wafer susceptor and a supportive and rotational connection apparatus matching the susceptor.

To attain the above object, a technical solution of one embodiment of the present invention provides an epitaxial wafer susceptor and a supportive and rotational connection apparatus matching the susceptor for a metal organic chemical vapour deposition (MOCVD), comprising: a susceptor which may be mechanically loaded and unloaded; and a vertical driving shaft, which is coupled to the susceptor; wherein the susceptor comprises: a top surface having a plurality of shallow concave disks for placing epitaxial wafers; and a susceptor rotating shaft protruding downward at a centor of a bottom of the susceptor; and wherein the driving shaft comprises a counter bore inside an upper end of the driving shaft; wherein the susceptor is placed via a robotic arm into a reaction chamber of the MOCVD where at least a part of the susceptor rotating shaft is inserted into the counter bore, wherein the susceptor is positioned and supported in the reaction chamber via coupling and connection between a contact surface of the susceptor rotating shaft and a corresponding contact surface of the counter bore, and wherein the susceptor is driven to rotate by the driving shaft if the driving shaft rotates; wherein reactant gases are introduced into the reaction chamber for an epitaxial reaction or a film deposition on the epitaxial wafers placed on the susceptor.

The epitaxial wafer susceptor and the supportive and rotational connection apparatus for the MOCVD system further comprise a rotation sealing apparatus, a rotation driving apparatus and a heater provided below the susceptor.

The driving shaft passes downward through the heater, comes out from the bottom of the reaction chamber through the rotation sealing apparatus and is connected with the rotation driving apparatus.

The driving shaft is driven to rotate by the rotation driving apparatus, and the susceptor rotates together with the driving shaft, so that the heater can heat the susceptor uniformly, and uniform reactant gas can be obtained on the epitaxial wafer.

In an embodiment, the susceptor rotating shaft is in the form of a downward protruding step, comprising a first boss provided on the bottom of the susceptor and a second boss with a smaller diameter provided below the first boss.

The annular end face at the bottom end of the first boss is parallel to both the top surface and the bottom surface of the susceptor.

The annular top surface of the counter bore is perpendicular to the axis of the driving shaft.

When the second boss of the susceptor rotating shaft is correspondingly inserted into the counter bore, the annular end face of the bottom end of the first boss comes into contact with the annular top surface of the counter bore, and the susceptor is thus supported and is driven to rotate by the driving shaft via friction transmission.

The height a1 of the second boss is less than the depth b1 of the counter bore so that when the second boss is completely inserted into the counter bore, a gap is formed between the bottom surface of the second boss and the bottom surface of the counter bore, and that the annular end face of the first boss can reliably contact the annular top surface of the counter bore.

The first boss is in the form of a cylinder; and the second boss is in the form of a cylinder or a cone with a diameter less than that of the first boss.

In another embodiment, when the downward-protruding susceptor rotating shaft is correspondingly inserted into the counter bore, the end face of the step at the bottom end of the susceptor rotating shaft comes into contact with the bottom surface of the counter bore, and the susceptor is thus supported and is driven to rotate by the driving shaft via friction transmission.

The end face of the step is parallel to both the top surface and the bottom surface of the susceptor.

The bottom surface of the counter bore is perpendicular to the axis of the driving shaft.

The height a2 of the susceptor rotating shaft is greater than the depth b2 of the counter bore so that a part of the susceptor rotating shaft is inserted into the counter bore and a gap is formed between the top surface of the driving shaft and the bottom surface of the susceptor, and that the end face of the step can reliably contact the bottom surface of the counter bore.

The susceptor rotating shaft is cylindrical or conic.

In yet another embodiment, the downward-protruding susceptor rotating shaft is correspondingly inserted into the counter bore with a shape matching therewith, and the side of the step of the susceptor rotating shaft comes into contact with the side of the counter bore of the driving shaft, the side of the step of the susceptor rotating shaft and the side of the counter bore of the driving shaft acting as the contact surfaces for friction transmission between the susceptor rotating shaft and the driving shaft, so that the driving shaft may drive the susceptor to rotate.

The susceptor rotating shaft is cylindrical or conic, and the driving shaft is cylindrical or conic.

In another embodiment, axial positioning apparatuses are respectively provided on the susceptor rotating shaft and the corresponding counter bore. When the driving shaft rotates, the susceptor is driven to rotate via the coupling between at least one pair of contact surfaces of the positioning apparatuses in the direction of rotation.

The axial positioning apparatuses are respectively positioning keys set on the side of the susceptor rotating shaft and positioning grooves correspondingly set on the side of the counter bore of the driving shaft.

When the susceptor rotating shaft is inserted into the counter bore, the locations of the positioning keys and the positioning grooves are aligned by an angular position sensor provided on the rotation driving apparatus. During rotation, the side end face of at least one positioning key comes into contact with the side end face of a positioning groove, so that the susceptor and the driving shaft rotate synchronously.

One embodiment of the present invention also provides a metal organic chemical vapor deposition (MOCVD), comprising: a reaction chamber (50); a circular susceptor (10) having a susceptor rotating shaft (100) protruding downward from a center of a bottom thereof; a vertical driving shaft (20 having a counter bore (200) inside an upper end thereof; wherein the susceptor (10) is placed in the reaction chamber (50) and at least a part of the susceptor rotating shaft (100) is correspondingly inserted into the counter bore (200), and wherein the driving shaft (20) is coupled and connected to the susceptor (10) for supporting the susceptor (10) and driving the susceptor (10) to rotate.

One embodiment of the present invention further provides an epitaxial wafer susceptor for a metal organic chemical vapor deposition (MOCVD) having a vertical driving shaft, comprising: a top surface (11) having a plurality of shallow concave disks for arranging epitaxial wafers (40); a bottom having a susceptor rotating shaft (100) protruding downward from a center of the bottom; wherein the susceptor rotating shaft (100) is adapted for at least partly inserting into a counter bore (200) inside an upper end of the driving shaft, whereby the driving shaft is coupled and connected to the susceptor (10) for supporting the susceptor (10) and driving the susceptor (10) to rotate.

In comparison with the prior art, the advantages of the present invention lie in that: an epitaxial wafer susceptor that can be mechanically loaded and unloaded is provided, wherein coupling and connection are realized by inserting a downward-protruding susceptor rotating shaft, which is provided at the center of the bottom of the susceptor, correspondingly into a counter bore inside the upper end of the driving shaft. Friction transmission is realized via a pair of contact end faces parallel to the surface of the susceptor that are respectively provided on the susceptor rotating shaft and the counter bore of the driving shaft, or via the contact between the side of the susceptor rotating shaft and the corresponding side of the counter bore of the driving shaft, so that the susceptor can rotate steadily at various required rotating speeds when it is driven by the driving shaft, and that the epitaxial wafers on the susceptor can be heated uniformly by the heater under the bottom of the susceptor, and that a boundary layer with a uniform gas concentration and a uniform gas speed can be obtained on the epitaxial wafers, and that epitaxial reaction or film deposition can be carried out on the epitaxial wafers.

Moreover, according to the present invention, several positioning grooves and positioning keys are correspondingly set on the sides of the susceptor rotating shaft and the counter bore of the driving shaft so that the rotation speeds of the susceptor and the driving shaft are synchronized via the transmission of the contact surface thereof in the direction of rotation. Therefore, component wearing caused by friction transmission may be avoided, the reliability of long-term use under high-speed and medium-speed rotation conditions may be improved, and susceptor substitute may be reduced, so that the production cost of epitaxial wafers may be reduced.

Because the susceptor rotating shaft has a downward-protruding structure, the contact surface with the driving shaft for friction transmission is outside the bottom of the susceptor, and therefore it is easy to conduct surface treatment.

With the protruding susceptor rotating shaft, the mechanical strength is guaranteed at the center of the susceptor without the need to additionally increase the overall thickness of the susceptor. Therefore, material consumption for manufacturing the susceptor is reduced, the weight of the susceptor is lightened, and the thermal capacity of the susceptor is reduced, so that the heating and cooling time of the susceptor is reduced, the production efficiency is improved, and the capability of temperature regulation and control for epitaxial reaction is also improved.

### BRIEF DESCRIPTION OF THE DRAWINGS

FIG. 1 is a schematic diagram showing the arrangement of plurality epitaxial wafers on a susceptor in an MOCVD system;

FIG. 2 is a structural representation of an existing MOCVD system for supporting a susceptor and driving the susceptor to rotate through the edge;

FIG. 3 is a structural representation of an existing MOCVD system for supporting a susceptor and driving the susceptor to rotate through the center;

FIG. 4 is a structural representation of another existing MOCVD system for supporting a susceptor and driving the susceptor to rotate through the center;

FIG. 5 is a schematic diagram showing the connection relation between an epitaxial wafer susceptor that can be mechanically loaded and unloaded along with a supportive and rotational connection apparatus and an MOCVD system;

FIG. 6 is a structural representation of an epitaxial wafer susceptor and a supportive and rotational connection apparatus for an MOCVD system between which transmission is realized via contact friction of parallel end faces according to embodiment 1 of the invention;

FIG. 7 is a structural representation of an epitaxial wafer susceptor and a supportive and rotational connection apparatus for an MOCVD system between which transmission is realized via contact friction of parallel end faces according to embodiment 2 of the invention;

FIG. 8 is a structural representation of an epitaxial wafer susceptor and a supportive and rotational connection apparatus for an MOCVD system between which transmission is realized via contact friction of sides according to embodiment 3 of the invention;

FIG. 9 is a structural representation of an epitaxial wafer susceptor and a supportive and rotational connection apparatus for an MOCVD system between which transmission is realized via stationary contact according to embodiment 4 of the invention;

FIG. 10 is a bottom view showing an structure of an end face of a susceptor rotating shaft for stationary contact transmission according to embodiment 4 of the invention; and

FIG. 11 is a top view showing an structure of an end face of a driving shaft for stationary contact transmission according to embodiment 4 of the invention.

### DETAILED DESCRIPTION OF THE EMBODIMENTS

A plurality of embodiments of the invention will now be illustrated below in conjunction with the drawings.

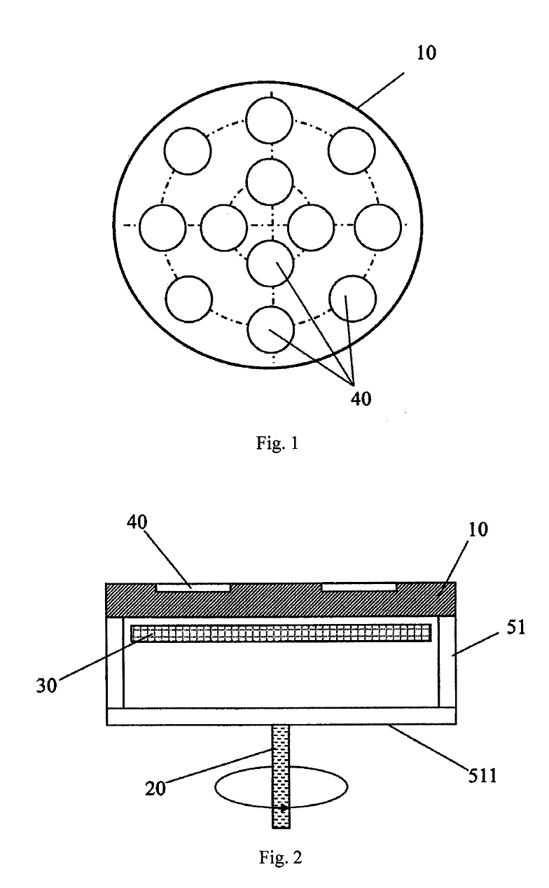

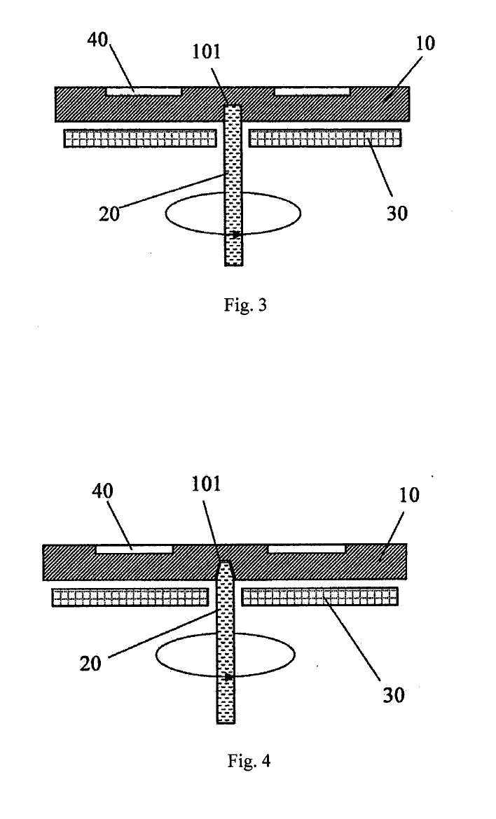

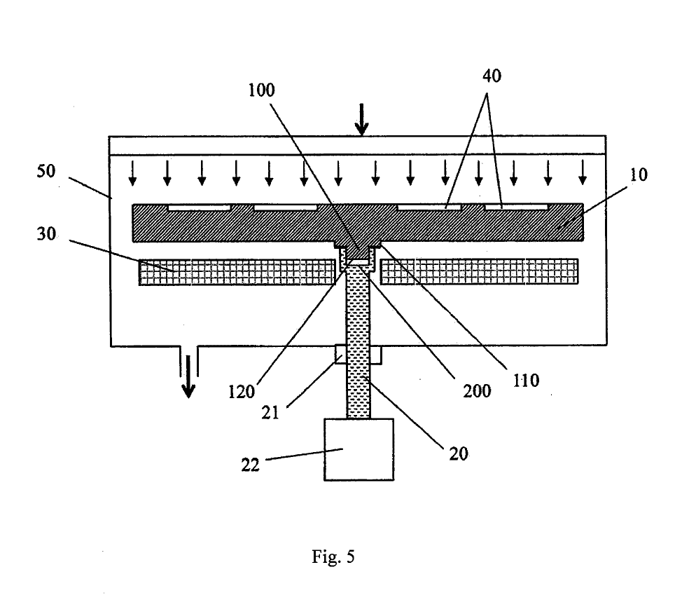

As shown in FIG. 5, a circular susceptor 10 that may be mechanically loaded and unloaded according to the invention is placed in a reaction chamber 50 of an MOCVD system; the top surface 11 of the susceptor 10 is parallel to the bottom surface 12, and a plurality of shallow concave disks are set on the top surface 11 around the center of the susceptor for arranging a plurality of epitaxial wafers 40 (FIG. 1). The rotating apparatus is a driving shaft 20 that is vertically provided. The susceptor 10 is placed and removed by a robotic arm, so that a susceptor rotating shaft 100 protruding downward from the center of the bottom of the susceptor is correspondingly inserted into a counter bore 200 set inside an upper end of the driving shaft 20, and thus the driving shaft 20 is coupled and connected to the susceptor 10. The driving shaft 20 passes downward through a heater 30 below the susceptor 10, and comes out from the bottom of the reaction chamber 50 through a rotation sealing apparatus 21 and is connected with a rotation driving apparatus 22.

Reactant gases enter from the top of the reaction chamber 50 and exit from the bottom part of the reaction chamber 50 after epitaxial reaction or film deposition is carried out on the epitaxial wafers 40 on the susceptor 10. During the processing of the epitaxial wafers 40, the motor of the rotation driving apparatus 22 drives the driving shaft 20 to rotate, and the susceptor 10 rotates synchronously with the driving shaft 20 via mutual coupling, so that the heater 30 can heat the susceptor 10 uniformly and uniform reactant gases on the epitaxial wafer 40 is obtained.

Because the susceptor rotating shaft 100 has a downward-protruding structure, the mechanical strength is guaranteed without the need to increase the overall thickness of the susceptor 10. Therefore, material consumption for manufacturing the susceptor 10 is reduced, and the weight of the susceptor 10 is lightened, and the thermal capacity of the susceptor is reduced.

Because the susceptor rotating shaft 100 has an outward-protruding structure, the contact surface of the rotating shaft contacting the driving shaft protrudes outside the bottom of the susceptor, and thus machining and treatment of the contact surface is easy to carry out.

The susceptor 10 that can be mechanically loaded and unloaded according to the invention is coupled with the driving shaft 20 under the center of the bottom of the susceptor. The following various structures may be employed to make the downward-protruding susceptor rotating shaft 100 contact the counter bore 200 of the driving shaft 20, and the rotation of the susceptor 10 driven by the driving shaft 20 is realized via friction transmission or contact transmission.

### Embodiment 1

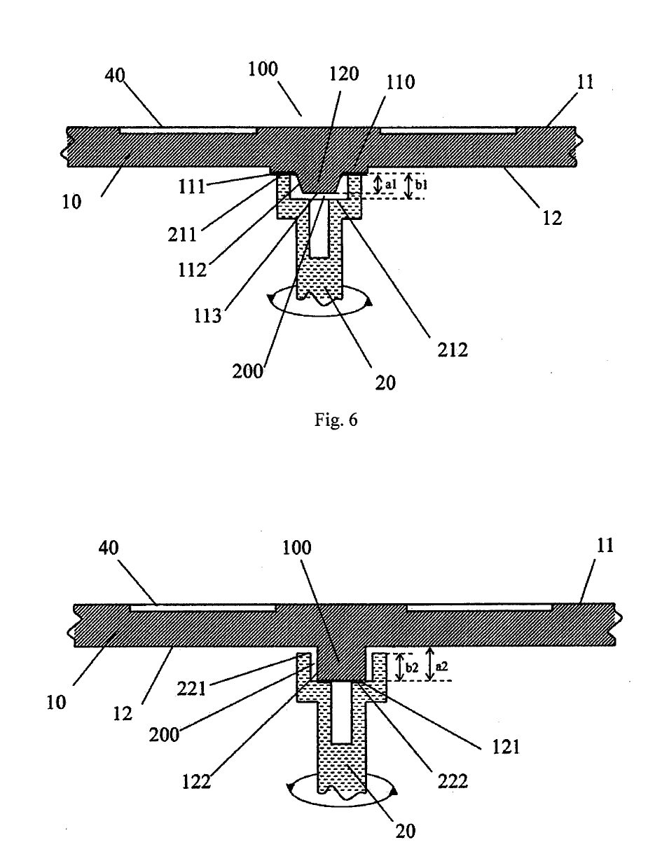

As shown in FIG. 5 or FIG. 6, in this embodiment, the susceptor rotating shaft 100 under the center location of the bottom of the susceptor 10 is in the form of a downward-protruding step, comprising a first boss 110 in the form of a cylinder provided on the bottom of the susceptor 10 and a second boss 120 in the form of a cylinder (FIG. 5) or a cone (FIG. 6) provided below the first boss 110 with a smaller diameter. The annular end face 111 of the first boss 110 is parallel to both the top surface 11 and the bottom surface 12 of the susceptor 10.

A counter bore 200 is set inside an upper end of the driving shaft 20, and the annular top surface 211 of the counter bore 200 is perpendicular to the axis of the driving shaft 20. When the susceptor 10 is placed into the reaction chamber 50, the second boss 120 of the susceptor rotating shaft 100 is completely inserted into the counter bore 200. The side 112 of the second boss 120 guides the susceptor 10 in the vertical direction and locates the susceptor 10 in a plane, so that the annular end face 111 of the first boss 110 with a larger diameter is placed on the annular top surface 211 of the driving shaft 20, and the susceptor 10 is positioned in the reaction chamber 50 in vertical direction and supported by the driving shaft 20. The effective area for supporting the susceptor 10 of the annular top surface 211 of the driving shaft 20 is determined by the inner and outer diameters of the counter bore 200 of the driving shaft 20.

The height a1 of the second boss 120 must be less than the depth b1 of the counter bore 200, so that when the second boss 120 is inserted into the counter bore 200, a gap is formed between the bottom surface 113 of the second boss 120 and the bottom surface 212 of the counter bore 200, and that a reliable contact between the annular end face 111 of the first boss 110 and the annular top surface 211 can be ensured. During epitaxial reaction, the annular end face 111 of the first boss 110 and the annular top surface 211 of the driving shaft 20 act as the contact surfaces for mutual friction transmission between the susceptor rotating shaft 100 and the driving shaft 20, so that the susceptor 10 is driven to rotate together with the driving shaft 20.

### Embodiment 2

As shown in FIG. 7, in this embodiment, the susceptor rotating shaft 100 at the center location on the bottom of the susceptor 10 is a cylindrical or conic (not shown in the figure) step protruding downward, and the end face 121 of the step is parallel to both the top surface 11 and the bottom surface 12 of the susceptor 10.

The susceptor rotating shaft 100 is positioned in a plane via its side 122 of the step. When the susceptor rotating shaft 100 is inserted into the counter bore 200 set inside an upper end of the driving shaft 20, the end face 121 of the step is located on the bottom surface 222 of the counter bore 200, so that the susceptor 10 is positioned in the reaction chamber 50 in vertical direction, and that the susceptor 10 is supported by the driving shaft 20. The effective area supporting the susceptor 10 of the bottom surface 222 of the counter bore 200 of the driving shaft 20 is determined by the diameter of the susceptor rotating shaft 100.

When the susceptor rotating shaft 100 is inserted into the counter bore 200, the end face 121 of the step matches and comes into contact with the bottom surface 222 of the counter bore 200. The end face 121 and the bottom surface 222 act as the contact surfaces for mutual friction transmission between the susceptor rotating shaft 100 and the driving shaft 20. The contact surfaces drive the susceptor 10 to rotate together with the driving shaft 20. The height a2 of the susceptor rotating shaft 100 must be greater than the depth b2 of the counter bore 200, so that a part of the susceptor rotating shaft 100 is inserted into the counter bore 200, and that a gap is formed between the top surface 221 of the driving shaft 20 and the bottom surface 12 of the susceptor 10, and that a reliable contact between the end face 121 of the step and the bottom surface 222 of the counter bore 200 can be guaranteed.

### Embodiment 3

The structure of embodiment 3 is different from the structure according to the above embodiments 1 and 2 in which the susceptor 10 is driven to rotate with the driving shaft 20 mainly via the matching between a pair of contact surfaces on the susceptor rotating shaft 100 and the driving shaft 20, which are parallel to the top surface 11 and the bottom surface 2 of the susceptor 10.

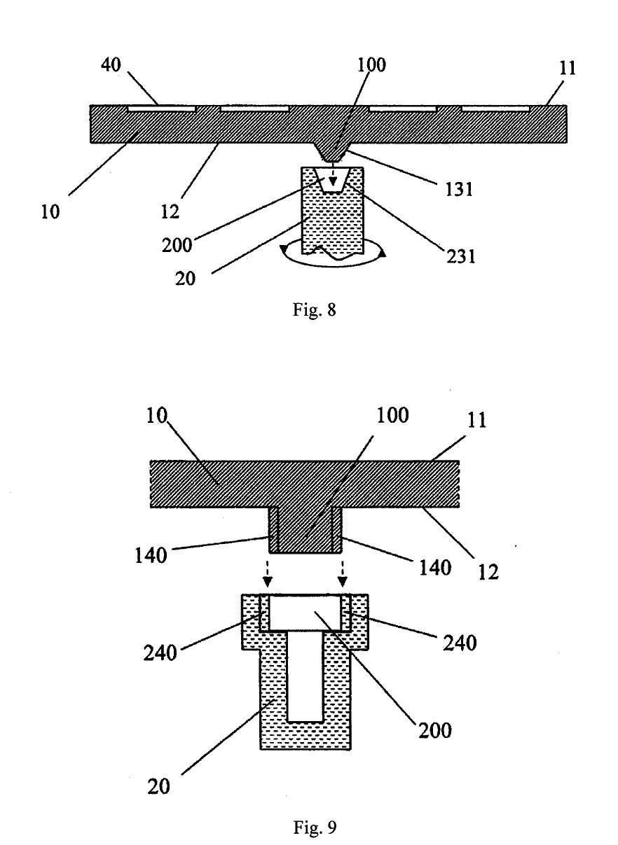

As shown in FIG. 8, in this embodiment, the susceptor rotating shaft 100 is provided with a step protruding downward from the bottom surface 12 of the susceptor 10, which may be cylindrical or conic; and correspondingly, the counter bore 200 inside the upper end of the driving shaft 20 is set as cylindrical or conic or other forms matching the susceptor rotating shaft 100, so that after the susceptor rotating shaft 100 is inserted into the counter bore 200, the side 131 of the step of the susceptor rotating shaft 100 comes into contact with the side 231 of the counter bore 200 of the driving shaft 20, and that the susceptor 10 is supported and the sides act as the contact surface for mutual friction transmission between the susceptor rotating shaft 100 and the driving shaft 20, and that the susceptor 10 is driven to rotate together with the driving shaft 20.

### Embodiment 4

As shown in FIG. 9 to FIG. 11, in some preferred embodiments, axial positioning apparatuses are respectively provided on the protruding susceptor rotating shaft 100 and the counter bore 200 of the driving shaft 20. Several pairs of contact surfaces in the direction of rotation are correspondingly added via the coupling of the positioning apparatuses, ensuring that the rotating speed of the susceptor 10 is consistent with the rotating speed of the driving shaft 20.

Specifically, a plurality of positioning keys 140 protruding outward may be set on the side of the susceptor rotating shaft 100, and a plurality of positioning grooves 240 with a form matching that of the positioning keys 140 are set at the corresponding locations on the side of the counter bore 200 of the driving shaft 20. When the susceptor 10 is placed into the reaction chamber 50, the locations of the positioning keys 140 and the positioning grooves 240 are aligned by an angular position sensor provided on the rotation driving apparatus 22, and the susceptor rotating shaft 100 is inserted into the counter bore 200, so that the side end face 141 of a positioning key 140 comes into contact with the side end face 241 of a positioning groove 240, and that the susceptor 10 is driven to rotate together with the driving shaft 20 via axial contact transmission, and that the rotating speed of the susceptor is kept consistent with the rotating speed of the driving shaft.

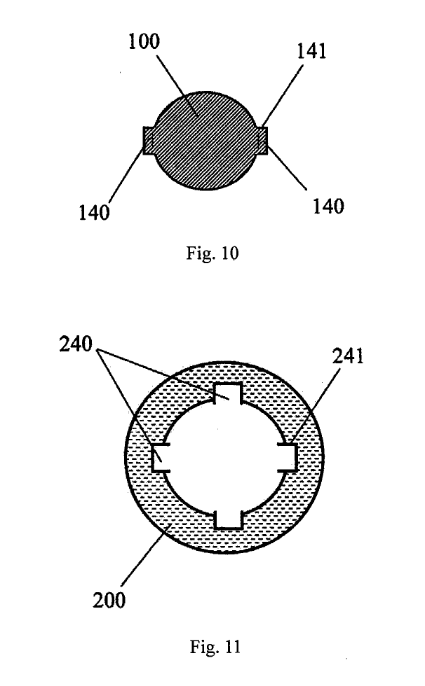

As shown in FIG. 10, it is a structural representation showing an optional structure of a pair of positioning keys 140 set on the susceptor rotating shaft 100. As shown in FIG. 11, it is a structural representation showing a cross-type positioning groove 240 set in the counter bore 200 of the driving shaft 20; in this case, the positioning keys 140 on the susceptor rotating shaft 100 may also be correspondingly set as cross type to increase the contact surface in the direction of rotation. Or else, the positioning keys 140 shown in FIG. 10 may be inserted into the cross-type positioning groove 240 shown in FIG. 11, and any pair of the positioning grooves 240 may match the positioning keys 140, which is convenient for positioning and aligning the susceptor 10 and the driving shaft 20.

Because several pairs of contact surfaces between the positioning grooves 240 and the positioning keys 140 are added in the direction of rotation, especially under the conditions of high-speed and medium-speed rotations, friction transmission is no longer needed when the driving shaft 20 drives the susceptor 10 to rotate synchronously, therefore the reliability of long-term use is improved and substitute of susceptor 10 due to wearing may be reduced, so that the production cost of the epitaxial wafer 40 may be reduced.

In conclusion, the invention provides a susceptor 10 for placing epitaxial wafers 40, wherein coupling and connection are realized by inserting a downward protruding susceptor rotating shaft 100, that is provided at the center of the bottom of the susceptor, into a counter bore 200 inside the upper end of a driving shaft 20, which is convenient for placing, removing and replacing the susceptor 10 in a reaction chamber 50 via a robotic arm.

In the invention, friction transmission is realized by a pair of contact end faces parallel to the surface of the susceptor 10 that are respectively provided on the susceptor rotating shaft 100 and the counter bore 200 of the driving shaft 20, or is realized via the contact between the side of the susceptor rotating shaft 100 and the corresponding side of the counter bore 200 of the driving shaft 20, so that the susceptor 10 may steadily rotate at various required rotating speeds when it is driven by the driving shaft 20. In addition, the epitaxial wafers 40 on the susceptor 10 may be uniformly heated by a heater 30 below the susceptor 10, and that a boundary layer with uniform gas concentration and uniform gas speed may be obtained on the epitaxial wafers 40, and that epitaxial reaction or film deposition may be carried out on the epitaxial wafers 40.

Moreover, according to the present invention, several pairs of corresponding positioning grooves 240 and positioning keys 140 may also be correspondingly set on the counter bore 200 of the driving shaft 20 and the sides of the susceptor rotating shaft 100, so that the rotating speeds of the susceptor 10 and the driving shaft 20 are synchronized via the engagement of the several pairs of contact surfaces in the direction of rotation. Therefore, friction transmission is not needed when the driving shaft 20 drives the susceptor 10 to rotate, especially under the conditions of high-speed and medium-speed rotations, thus the reliability of long-term use may be improved, and substitute of susceptor 10 due to wearing may be reduced, so that the production cost of the epitaxial wafer 40 may be reduced.

Additionally, because the susceptor rotating shaft 100 has a downward-protruding structure, the contact surface in friction with the driving shaft 20 is outside the bottom of the susceptor 10, and therefore it is easy to conduct surface treatment.

Moreover, with the protruding susceptor rotating shaft 100, the mechanical strength at the center of the susceptor can be guaranteed without the need to additionally increasing the overall thickness of the susceptor 10. Therefore, material consumption for manufacturing the susceptor 10 is reduced, the weight of the susceptor 10 is lightened, and its thermal capacity is reduced, so that the heating and cooling time of the susceptor 10 is reduced, the production efficiency is improved, and the capability of temperature regulation and control for epitaxial reaction is also improved.

Although the contents of the invention have been introduced in detail with the above preferred embodiments, it should be noted that, the above description should not be construed as limiting the scope of the invention. Various modifications and substitutions are apparent to an skilled in the art on reading the above contents. Therefore, the protection scope of the invention should be defined by the appended claims.

What is claimed is:

1. An epitaxial wafer susceptor and a supportive and rotational connection apparatus matching the epitaxial wafer susceptor for a metal organic chemical vapour deposition (MOCVD), comprising:
a susceptor (10) which is capable of being mechanically loaded and unloaded; and
a vertical driving shaft (20), which is coupled to the susceptor (10);
wherein the susceptor (10) comprises: a top surface (11) having a plurality of shallow concave disks for placing epitaxial wafers (40); and a susceptor rotating shaft (100) protruding downward at a center of a bottom of the susceptor (10);
wherein the driving shaft (20) comprises a counter bore (200) inside an upper end of the driving shaft (20);
wherein the susceptor (10) is placed via a robotic arm into a reaction chamber (50) of the MOCVD where at least a part of the susceptor rotating shaft (100) is inserted into the counter bore (200), wherein the susceptor (10) is positioned and supported in the reaction chamber (50) via coupling and connection between a contact surface of the susceptor rotating shaft (100) and a corresponding contact surface of the counter bore (200), and wherein the susceptor (10) is driven to rotate by the driving shaft (20) if the driving shaft (20) rotates;
wherein reactant gases are introduced into the reaction chamber (50) for an epitaxial reaction or a film deposition on the epitaxial wafers (40) placed on the susceptor (10).

2. The epitaxial wafer susceptor and the supportive and rotational connection apparatus matching the epitaxial wafer susceptor according to claim 1, further comprising: a rotation sealing apparatus (21), a rotation driving apparatus (22) and a heater (30) provided below the susceptor (10);
wherein the driving shaft (20) passes downward through the heater (30), comes out from a bottom of the reaction chamber (50) through the rotation sealing apparatus (21) and is connected with the rotation driving apparatus (22);
wherein the driving shaft (20) is driven to rotate by the rotation driving apparatus (22), and the susceptor (10) is driven to rotate together with the driving shaft (20).

3. The epitaxial wafer susceptor and the supportive and rotational connection apparatus matching the epitaxial wafer susceptor according to claim 1, characterized in that, the susceptor rotating shaft (100) is in a form of a downward protruding step comprising a first boss (110) provided on the bottom of the susceptor (10) and a second boss (120) provided below the first boss (110);
an annular end face (111) at a bottom end of the first boss (110) is parallel to both the top surface (11) and a bottom surface (12) of the susceptor (10);
an annular top surface (211) of the counter bore (200) is perpendicular to an axis of the driving shaft (20);
a height a1 of the second boss (120) is less than a depth b1 of the counter bore (200);
wherein the second boss (120) of the susceptor rotating shaft (100) is inserted into the counter bore (200) correspondingly, whereby the annular end face (111) comes into contact with the annular top surface (211) of the counter bore (200), and the susceptor (10) is supported and is driven to rotate by friction transmission if the driving shaft (20) rotates.

4. The epitaxial wafer susceptor and the supportive and rotational connection apparatus matching the epitaxial wafer susceptor according to claim 3, characterized in that, the first boss (110) is in a form of cylinder; and the second boss (120) is in a form of a cylinder or a cone with a diameter less than that of the first boss (110).

5. The epitaxial wafer susceptor and the supportive and rotational connection apparatus matching the epitaxial wafer susceptor according to claim 1, characterized in that, wherein the susceptor rotating shaft (100) protruding downward is correspondingly inserted into the counter bore (200), whereby an end face (121) of the step at a bottom end of the susceptor rotating shaft (100) comes into contact with a bottom surface (222) of the counter bore (200), and the susceptor (10) is supported and is driven to rotate by friction transmission if the driving shaft (20) rotates;
the end face (121) of the step is parallel to both the top surface (11) and a bottom surface (12) of the susceptor (10);
the bottom surface (222) of the counter bore (200) is perpendicular to the axis of the driving shaft (20); and
a height a2 of the susceptor rotating shaft (100) is greater than a depth b2 of the counter bore (200).

6. The epitaxial wafer susceptor and the supportive and rotational connection apparatus matching the epitaxial wafer susceptor according to claim 5, characterized in that, the susceptor rotating shaft (100) is cylindrical or conic.

7. The epitaxial wafer susceptor and the supportive and rotational connection apparatus matching the epitaxial wafer susceptor according to claim 1, characterized in that, the susceptor rotating shaft (100) protruding downward is correspondingly inserted into the counter bore (200) matching a shape of the susceptor rotating shaft (100), and the susceptor (10) is supported by a contact between a side (131) of a step of the susceptor rotating shaft (100) and a side (231) of the counter bore (200) of the driving shaft (20), and the side (131) of the step of the susceptor rotating shaft (100) and the side (231) of the counter bore (200) of the driving shaft (20) act as contact surfaces for mutual friction transmission between the susceptor rotating shaft (100) and the driving shaft (20), so that the driving shaft (20) is capable of driving the susceptor (10) to rotate.

8. The epitaxial wafer susceptor and the supportive and rotational connection apparatus matching the epitaxial wafer susceptor according to claim 1, characterized in that, a plurality of axial positioning apparatuses are respectively provided on the susceptor rotating shaft (100) and the counter bore (200) of the driving shaft (20), and the driving shaft (20) is capable of driving the susceptor (10) to rotate via coupling between at least one pair of contact surfaces of the positioning apparatuses in a direction of rotation.

9. The epitaxial wafer susceptor and the supportive and rotational connection apparatus matching the epitaxial wafer susceptor according to claim 8, characterized in that, the axial positioning apparatuses are respectively positioning keys (140) set on a side of the susceptor rotating shaft (100) and positioning grooves (240) correspondingly set on a side of the counter bore (200) of the driving shaft (20);
wherein the susceptor rotating shaft (100) is inserted into the counter bore (200), and the locations of the positioning keys (140) and the positioning grooves (240) are aligned by an angular position sensor provided on the rotation driving apparatus (22), so that the positioning keys (140) and the positioning grooves (240) are precisely coupled.

10. A metal organic chemical vapor deposition (MOCVD), comprising:
a reaction chamber (50);
a circular susceptor (10) having a susceptor rotating shaft (100) protruding downward from a center of a bottom thereof;
a vertical driving shaft (20 having a counter bore (200) inside an upper end thereof;
wherein the susceptor (10) is placed in the reaction chamber (50) and at least a part of the susceptor rotating shaft (100) is correspondingly inserted into the counter bore (200), and wherein the driving shaft (20) is coupled and connected to the susceptor (10) for supporting the susceptor (10) and driving the susceptor (10) to rotate.

11. The MOCVD according to claim 10, wherein the susceptor (10) is placed in the reaction chamber (50) via a robotic arm.

12. The MOCVD according to claim 10, wherein a contact surface of the susceptor rotating shaft (100) is coupled and connected to a contact surface of the counter bore (200).

13. The MOCVD according to claim 10, wherein a top surface (11) of the susceptor comprises a plurality of shallow concave disks for arranging epitaxial wafers (40).

14. The MOCVD according to claim 13, wherein the reactant gases are introduced into the reaction chamber (50) for epitaxial reaction on the epitaxial wafers (40).

15. The MOCVD according to claim 10, wherein the susceptor rotating shaft (100) comprises a step protruding downward from a bottom surface (12) of the susceptor (10), and wherein the step is cylindrical or conic.

16. The MOCVD according to claim 15, wherein the counter bore (200) is cylindrical or conic.

17. An epitaxial wafer susceptor for a metal organic chemical vapor deposition (MOCVD) having a vertical driving shaft, comprising:
a top surface (11) having a plurality of shallow concave disks for arranging epitaxial wafers (40);
a bottom having a susceptor rotating shaft (100) protruding downward from a center of the bottom;
wherein the susceptor rotating shaft (100) is adapted for at least partly inserting into a counter bore (200) inside an upper end of the driving shaft, whereby the driving shaft is coupled and connected to the susceptor (10) for supporting the susceptor (10) and driving the susceptor (10) to rotate.

18. The susceptor according to claim 17, wherein a contact surface of the susceptor rotating shaft (100) is coupled and connected to a contact surface of the counter bore (200).

19. The susceptor according to claim 17, wherein the susceptor rotating shaft (100) comprises a step protruding downward from a bottom surface (12) of the susceptor (10), and wherein the step is cylindrical or conic.

20. The susceptor according to claim 17, wherein the susceptor rotating shaft (100) comprises a pair of positioning keys (140) on a side thereof, adapted for matching a pair of positioning grooves (240) on a side of the counter bore (200).
